(19) United States
(12) Patent Application Publication
(10) Pub. No.: US 2025/0311451 A1
(43) Pub. Date: Oct. 2, 2025

(54) SEMICONDUCTOR APPARATUS AND METHOD FOR MANUFACTURING SEMICONDUCTOR APPARATUS

(71) Applicant: CANON KABUSHIKI KAISHA, Tokyo (JP)

(72) Inventor: TSUTOMU TANGE, Kanagawa (JP)

(21) Appl. No.: 19/082,463

(22) Filed: Mar. 18, 2025

(30) Foreign Application Priority Data
Mar. 26, 2024 (JP) 2024-050285

(51) Int. Cl. H10F 39/00; H10F 39/12; H10F 71/00; H10F 77/12

(52) U.S. Cl. CPC H10F 39/026; H10F 39/12; H10F 39/811; H10F 71/136; H10F 77/1275

(57) ABSTRACT

A method for manufacturing a semiconductor apparatus includes a step of preparing a first semiconductor substrate, a second semiconductor substrate including a first semiconductor layer and a second semiconductor layer, and a third semiconductor substrate, a bonding step of bonding the second semiconductor substrate and the third semiconductor substrate to one main surface of the first semiconductor substrate, and a thinning step of removing at least the second semiconductor layer of the second semiconductor substrate by wet etching after the bonding step. The first semiconductor layer includes a P− type impurity region or an N− type impurity region, the second semiconductor layer includes a P+ region. An etching rate of an etchant used in the thinning step for the second semiconductor layer is higher than an etching rate for the first semiconductor layer.

### BACKGROUND OF THE INVENTION

### Field of the Invention

The present invention relates to a semiconductor apparatus and a method for manufacturing a semiconductor apparatus.

### Description of the Related Art

In recent years, downsizing and performance improvement of semiconductor apparatuses have been achieved by stacking a plurality of chips provided with semiconductor elements. JP2022-089275 A proposes a technology related to a chip on wafer (CoW) in which a chip on which a circuit such as a signal processing circuit or a memory circuit is formed and a wafer on which an imaging element is formed are bonded using Cu—Cu bonding.

In a case where a plurality of semiconductor chips are bonded to a wafer using a chip on wafer (CoW) process, there is a possibility that the plurality of chips are bonded in a state in which heights thereof vary. When bonding is performed in a state in which the heights vary, it is difficult to sufficiently eliminate a variation in height even if planarization is attempted by a technique such as chemical mechanical polishing (CMP) thereafter.

When the heights of the semiconductor chips bonded to the wafer vary, an electronic component may not exhibit desired performance for a use as an electronic component. In addition, in a case where the wafer to which the plurality of semiconductor chips are bonded is diced to cut out a plurality of electronic components, the heights of the bonded semiconductor chips vary for each cutout electronic component. Therefore, for example, in a case where the electronic component is an imaging apparatus, there is a possibility that imaging sensitivity varies for each imaging apparatus. In addition, in a case where a process of further bonding another substrate to the wafer to which the plurality of semiconductor chips are bonded is performed, there is a possibility that a bonding failure due to the variation in height of the chips occurs. Further, it has been desired to reduce noise from an interface opposite to a bonding surface of the bonded semiconductor chip.

### SUMMARY OF THE INVENTION

According to a first aspect of the present invention, a method for manufacturing a semiconductor apparatus includes a step of preparing a first semiconductor substrate, a second semiconductor substrate including a first semiconductor layer and a second semiconductor layer, and a third semiconductor substrate, a bonding step of bonding the second semiconductor substrate and the third semiconductor substrate to one main surface of the first semiconductor substrate, and a thinning step of removing at least the second semiconductor layer of the second semiconductor substrate by wet etching after the bonding step. The first semiconductor layer includes a P− type impurity region or an N− type impurity region, the second semiconductor layer includes a P+ region. An etching rate of an etchant used in the thinning step for the second semiconductor layer is higher than an etching rate for the first semiconductor layer.

According to a second aspect of the present invention, a semiconductor apparatus includes a first semiconductor substrate, and a second semiconductor substrate. A main surface of the first semiconductor substrate including an imaging element, and a main surface of the second semiconductor substrate including a circuit portion are bonded to each other. The main surface of the second semiconductor substrate is larger in area than the main surface of the first semiconductor substrate. The first semiconductor substrate includes a P− type impurity region or an N− type impurity region at a position where a distance from a surface opposite to the second semiconductor substrate exceeds 100 nm, and a maximum value of a P type impurity concentration in a range within 100 nm from the surface opposite to the second semiconductor substrate is higher than a P type impurity concentration in the P− type impurity region or the N− type impurity region and lower than 1×10¹⁹ [atoms/cm³].

According to a third aspect of the present invention, a semiconductor apparatus includes a first semiconductor substrate, and a second semiconductor substrate. A main surface of the first semiconductor substrate including a circuit portion, and a main surface of the second semiconductor substrate including an imaging element are bonded to each other. The main surface of the second semiconductor substrate is larger in area than the main surface of the first semiconductor substrate. The first semiconductor substrate includes a P− type impurity region or an N− type impurity region at a position where a distance from a surface opposite to the second semiconductor substrate exceeds 100 nm, and a maximum value of a P type impurity concentration in a range within 100 nm from the surface opposite to the second semiconductor substrate is higher than a P type impurity concentration in the P− type impurity region or the N− type impurity region and lower than 1×10¹⁹ [atoms/cm³].

According to a fourth aspect of the present invention, a semiconductor apparatus includes a first semiconductor substrate, a second semiconductor substrate, and a third semiconductor substrate. The second semiconductor substrate and the third semiconductor substrate are bonded to a main surface of a first semiconductor substrate that is larger in area than a main surface of the second semiconductor substrate and a main surface of the third semiconductor substrate. A main surface of the second semiconductor substrate that is opposite to the first semiconductor substrate and a main surface of the third semiconductor substrate that is opposite to the first semiconductor substrate are disposed along a plane parallel to the main surface of the first semiconductor substrate. The second semiconductor substrate and the third semiconductor substrate include a P− type impurity region or an N− type impurity region at a position where a distance from a surface opposite to the first semiconductor substrate exceeds 100 nm, and a maximum value of a P type impurity concentration in a range within 100 nm from the surface opposite to the first semiconductor substrate is higher than a P type impurity concentration in the P− type impurity region or the N− type impurity region and lower than 1×10¹⁹ [atoms/cm³].

Further features of the present invention will become apparent from the following description of exemplary embodiments with reference to the attached drawings.

### BRIEF DESCRIPTION OF THE DRAWINGS

FIG. 1 is a schematic cross-sectional view illustrating a cross section of a semiconductor apparatus according to a first embodiment taken in a direction perpendicular to a main surface of a semiconductor substrate.

FIG. 2 is a schematic cross-sectional view illustrating one stage in a manufacturing process for the semiconductor apparatus according to the first embodiment.

FIG. 3 is a schematic cross-sectional view illustrating another stage in the manufacturing process for the semiconductor apparatus according to the first embodiment.

FIG. 4 is a schematic cross-sectional view illustrating another stage in the manufacturing process for the semiconductor apparatus according to the first embodiment.

FIG. 5 is a schematic cross-sectional view illustrating another stage in the manufacturing process for the semiconductor apparatus according to the first embodiment.

FIG. 6 is a schematic cross-sectional view illustrating one stage in a manufacturing process for a semiconductor apparatus according to a second embodiment.

FIG. 7 is a schematic cross-sectional view illustrating another stage in the manufacturing process for the semiconductor apparatus according to the second embodiment.

FIG. 8 is a schematic cross-sectional view illustrating a cross section of a semiconductor apparatus according to a third embodiment taken in a direction perpendicular to a main surface of a semiconductor substrate.

FIG. 9 is a schematic cross-sectional view illustrating one stage in a manufacturing process for the semiconductor apparatus according to the third embodiment.

FIG. 10 is a schematic cross-sectional view illustrating another stage in the manufacturing process for the semiconductor apparatus according to the third embodiment.

FIG. 11 is a schematic cross-sectional view illustrating another stage in the manufacturing process for the semiconductor apparatus according to the third embodiment.

FIG. 12 is a schematic cross-sectional view illustrating one stage in a manufacturing process for a semiconductor apparatus according to a fourth embodiment.

FIG. 13 is a schematic cross-sectional view illustrating another stage in the manufacturing process for the semiconductor apparatus according to the fourth embodiment.

FIG. 14 is a schematic cross-sectional view illustrating another stage in the manufacturing process for the semiconductor apparatus according to the fourth embodiment.

FIG. 15 is a schematic cross-sectional view illustrating another stage in the manufacturing process for the semiconductor apparatus according to the fourth embodiment.

FIG. 16A is a schematic diagram for describing equipment according to a fifth embodiment.

FIG. 16B is a schematic diagram illustrating an example of a photoelectric conversion system according to the fifth embodiment.

FIG. 16C is a schematic diagram illustrating an example of an in-vehicle photoelectric conversion system according to the fifth embodiment.

### DESCRIPTION OF THE EMBODIMENTS

Semiconductor apparatuses, methods for manufacturing a semiconductor apparatus, and the like according to embodiments of the present invention will be described with reference to the drawings. The embodiments described below are merely examples, and for example, detailed configurations can be appropriately changed and implemented by those skilled in the art without departing from the gist of the present invention.

In the drawings referred to in the following embodiments and description, elements denoted by the same reference signs have similar functions unless otherwise specified. In the drawings, in a case where a plurality of the same elements are arranged, reference signs and a description thereof may be omitted.

In addition, the drawings may be schematic for convenience of illustration and description, and thus, the shape, size, arrangement, and the like of elements in the drawings may not strictly match those of actual ones. In addition, “XX or more and YY or less” or “XX toYY” representing a numerical range means a numerical range including end points XX (lower limit) and YY (upper limit) unless otherwise specified. When numerical ranges are described in stages, the upper limit and the lower limit of each numerical range can be arbitrarily combined.

Note that seeing through the semiconductor apparatus from a direction perpendicular to a main surface of a semiconductor layer is referred to as a plan view of the semiconductor apparatus.

In the following description, a P type semiconductor region is used as a generic term including a P+ type impurity region and a P− type impurity region. In the P type semiconductor region, an impurity region having a relatively low net impurity concentration (for example, boron concentration) is referred to as the P− type impurity region, and an impurity region having a relatively high net impurity concentration (for example, boron concentration) is referred to as the P+ type impurity region. The net impurity concentration (for example, boron concentration) of the P+ type impurity region is, for example, 4×10¹⁸ [atoms/cm³] or more. In the P+ type impurity region, particularly an impurity region whose net impurity concentration exceeds 1×10²⁰ [atoms/cm³] may be referred to as a P++ type impurity region. The net impurity concentration of the P− type impurity region is, for example, 2×10¹⁵ [atoms/cm³] or less. The P type semiconductor region can include a P type impurity region whose impurity concentration is higher than 2×10¹⁵ [atoms/cm³] and lower than 4×10¹⁸ [atoms/cm³].

In addition, an N type semiconductor region is used as a generic term including an N+ type impurity region and an N-type impurity region. In the N type semiconductor region, an impurity region having a relatively low net impurity concentration (for example, arsenic concentration or phosphorus concentration) is referred to as an N− type impurity region, and an impurity region having a relatively high net impurity concentration (for example, arsenic concentration or phosphorus concentration) is referred to as an N+ type impurity region.

The net impurity concentration (for example, arsenic concentration or phosphorus concentration) of the N+ type impurity region is, for example, 1×10¹⁸ [atoms/cm³] or more. The net impurity concentration of the N− type impurity region is, for example, 6×10¹⁴ [atoms/cm³] or less. The N type semiconductor region can include an impurity region whose impurity concentration is higher than 6×10¹⁴ [atoms/cm³] and lower than 1×10¹⁸ [atoms/cm³].

### First Embodiment

### Configuration of Semiconductor Apparatus

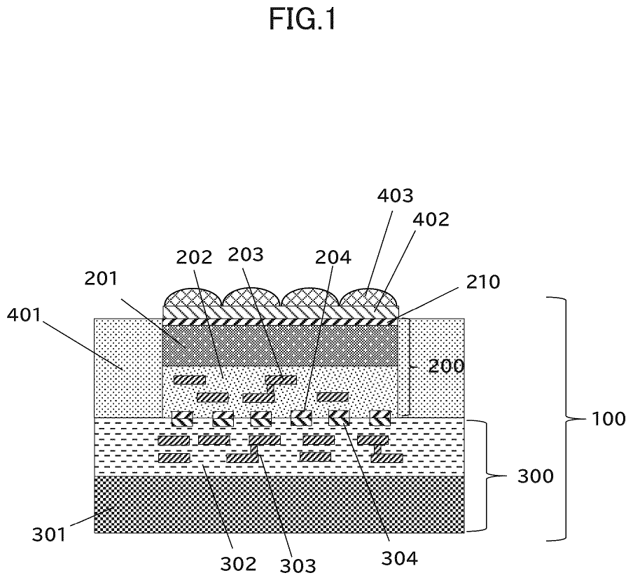

A semiconductor apparatus (solid-state imaging apparatus) according to a first embodiment will be described with reference to the drawing. FIG. 1 is a schematic cross-sectional view illustrating a cross section of a semiconductor apparatus 100 according to the present embodiment taken in a direction perpendicular to a main surface of a semiconductor substrate. The semiconductor apparatus 100 is a back-illuminated stacked sensor using a chip on wafer (CoW) technology, and an imaging element 200 and a circuit portion 300 are bonded to form an integrated structure.

The imaging element 200 includes a first semiconductor layer 201, an interlayer wiring film 202 (interlayer insulating film), and a wiring layer 203. A photodiode (not illustrated) serving as a photoelectric conversion unit is formed in the first semiconductor layer 201, and the interlayer wiring film 202 and the wiring layer 203 are stacked under the first semiconductor layer 201. A metal layer 204 electrically connected to the wiring layer 203 is disposed on a lower surface (a surface opposite to the first semiconductor layer 201) of the interlayer wiring film 202. The metal layer 204 contains, for example, copper as a main component, and the interlayer wiring film 202 contains, for example, silicon oxide as a main component. Note that the main component is a component having the largest weight when there are a plurality of components (materials) contained in a member, and in the present specification, the largest weight means that the component occupies 50 wt % or more.

Optical structures such as a color filter 402 and a microlens 403 are disposed on a light receiving surface side (an upper side in FIG. 1) of the imaging element 200. It is also possible to form, for example, a dielectric layer having a fixed charge, a light shielding structure, or a light guiding structure between the light receiving surface side (opposite to the circuit portion 300) of the imaging element 200 and the color filter 402.

The first semiconductor layer 201 includes a high-concentration P type impurity region 210 on the outermost surface on the light receiving surface side (opposite to the circuit portion 300). As the first semiconductor layer 201 includes the high-concentration P type impurity region 210, it is possible to reduce an influence of noise from an interface in the imaging element 200.

Silicon oxide 401 is formed in contact with a side surface of the imaging element 200 so as to surround the imaging element 200 in plan view of the semiconductor apparatus 100 in a direction perpendicular to a main surface of the first semiconductor layer 201.

The circuit portion 300 includes a second semiconductor layer 301 in which a transistor and the like are formed, an interlayer wiring film 302 (interlayer insulating film), and a wiring layer 303. The circuit portion 300 includes at least some of a drive circuit that drives the imaging element 200 to read a signal, a control circuit, a signal processing circuit, an output circuit, and the like. A metal layer 304 electrically connected to the wiring layer 303 is disposed on an upper surface (a surface adjacent to the first semiconductor layer 201) of the interlayer wiring film 302. The metal layer 304 contains, for example, copper as a main component, and the interlayer wiring film 302 contains, for example, silicon oxide as a main component.

The imaging element 200 and the circuit portion 300 are bonded to each other by a predetermined bonding method. For example, the metal layer 204 and the metal layer 304 are bonded by metal bonding of Cu—Cu, and the interlayer wiring film 202 and the interlayer wiring film 302 are bonded by covalent bonding of silicon oxide. As the metal layer 204 and the metal layer 304 are bonded to each other, a wiring included in the imaging element 200 and a wiring included in the circuit portion 300 are electrically connected to form an electric circuit network of the semiconductor apparatus 100.

If the circuit portion 300 is referred to as a wafer and the imaging element 200 is referred to as a chip, a chip on wafer (CoW) structure in which the chip is disposed on the wafer having a relatively large area in plan view is formed. In other words, the chip having a relatively small area in plan view is stacked on a main surface of the wafer, and the chip forms a protrusion protruding from the main surface of the wafer.

As is clear from a description of a manufacturing method described below, in the first semiconductor layer 201 of the chip, a P− type impurity region or an N-type impurity region is disposed at a position where a distance (depth) from the surface opposite to the circuit portion 300 exceeds 100 nm. In the P type impurity region 210 disposed on the surface opposite to the circuit portion 300 in the chip, a maximum value of a P type impurity concentration in a range within 100 nm from the surface opposite to the circuit portion 300 is higher than a P type impurity concentration in the P− type impurity region or the N− type impurity region. Further, in the P type impurity region 210 of the chip, the maximum value of the P type impurity concentration in the range within 100 nm from the surface opposite to the circuit portion 300 is lower than 1×10¹⁹ [atoms/cm³].

In the semiconductor apparatus 100 according to the present embodiment having such a structure, a height of the imaging element 200 as the chip has a predetermined value, and the high-concentration P type impurity region 210 is provided at the interface, so that a pinning effect can be obtained, and the influence of noise (for example, a dark current) can be reduced.

### Method for Manufacturing Semiconductor Apparatus

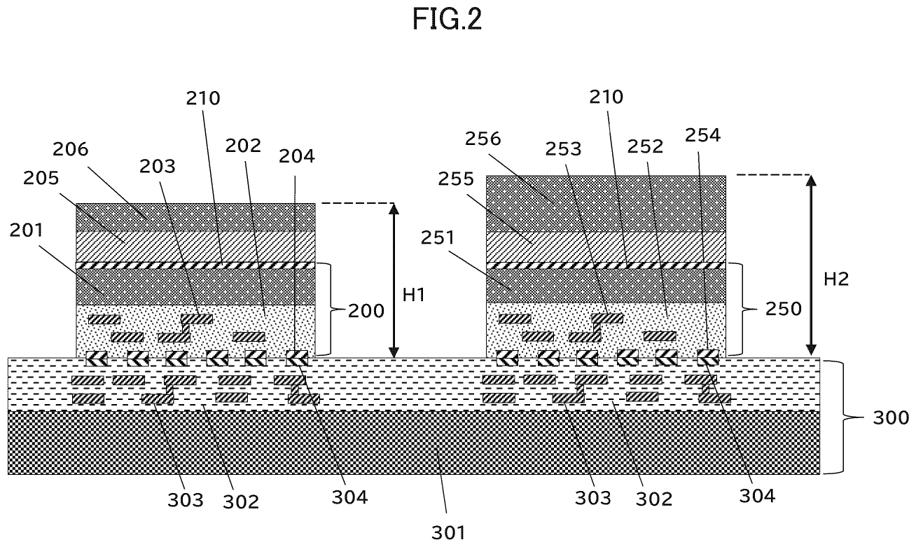

Next, a method for manufacturing the semiconductor apparatus 100 according to the present embodiment will be described with reference to FIGS. 2 to 5. FIGS. 2 to 5 are schematic cross-sectional views each illustrating a state in each stage of a manufacturing process, taken in a direction perpendicular to a main surface of the second semiconductor layer 301.

First, the circuit portion 300 in a wafer state, and the imaging element 200 and an imaging element 250 having a chip shape are prepared.

Next, as illustrated in FIG. 2, the imaging element 200 and the imaging element 250 having the chip shape are bonded to the circuit portion 300 in the wafer state. For example, the metal layer 304 mainly containing Cu is disposed in the circuit portion 300, the metal layer 204 mainly containing Cu is disposed in the imaging element 200, and a metal layer 254 mainly containing Cu is disposed in the imaging element 250. The circuit portion 300 and the imaging element 200 are bonded by metal bonding of Cu—Cu between the metal layers and covalent bonding between the interlayer wiring film 202 and the interlayer wiring film 302. The circuit portion 300 and the imaging element 250 are bonded by metal bonding of Cu—Cu between the metal layers and covalent bonding between an interlayer wiring film 252 and the interlayer wiring film 302. As a diffusion prevention structure made of, for example, silicon nitride is formed in a part of the interlayer wiring film 202, the interlayer wiring film 252, and the interlayer wiring film 302, it is possible to suppress diffusion of metal elements contained in the metal layer 304, the metal layer 204, and the metal layer 254.

Here, the imaging element 200 and the imaging element 250 having the chip shape and bonded to the circuit portion 300 are integrally formed on a semiconductor wafer, separated by dicing, and cut out as chips. The imaging element 200 and the imaging element 250 are attached with a layer that is not necessary to finally function as an imaging element but is necessary in a process up to manufacturing. For example, an impurity layer 205 and a semiconductor layer 206 are attached to the chip of the imaging element 200, and an impurity layer 255 and a semiconductor layer 256 are attached to the chip of the imaging element 250.

The semiconductor layer 206 attached to the chip of the imaging element 200 and the semiconductor layer 256 attached to the chip of the imaging element 250 are, for example, N type semiconductor substrates, and may also be P type semiconductor substrates.

The imaging element 200 and the imaging element 250 are cut out from a plurality of imaging elements formed on the wafer, and before the imaging element 200 and the imaging element 250 are cut out, thicknesses of portions corresponding to the semiconductor layer 206 and the semiconductor layer 256 after being cut out are not necessarily uniform. Even in a case where the uppermost semiconductor layer is thinned and planarized by, for example, chemical mechanical polishing (CMP) in a wafer stage, the thickness of the semiconductor layer varies in a wafer plane (for example, a central portion and a peripheral portion of the wafer). In addition, the thickness of the semiconductor layer after planarization by the CMP varies for each wafer. Therefore, the thickness of the semiconductor layer 206 attached to the imaging element 200 cut out as the chip and the thickness of the semiconductor layer 256 attached to the imaging element 250 vary.

The impurity layer 205 attached to the chip of the imaging element 200 and the impurity layer 255 attached to the chip of the imaging element 250 are P+ type impurity regions, and are high-concentration P type impurity layers having an impurity concentration of 1×10¹⁹ [atoms/cm³] or more, for example.

The impurity layer 205 and the impurity layer 255, which are the high-concentration P type impurity layers, are formed before the imaging element is cut out as the chip, and there are various formation methods. Examples of a first method include a method of forming the high-concentration P type impurity layer 205 and the high-concentration P type impurity layer 255 by epitaxial growth before forming a transistor or the like in the first semiconductor layer. Examples of a second method include a method of forming the high-concentration P type impurity layer 205 and the high-concentration P type impurity layer 255 by impurity implantation.

The first semiconductor layer 201 of the imaging element 200 and the first semiconductor layer 251 of the imaging element 250 are, for example, N type epi layers, and thicknesses thereof are extremely close to each other. The first semiconductor layer 201 and the first semiconductor layer 251 include a device formation region where a photodiode, a transistor, and the like are formed. In the first semiconductor layer 201 and the first semiconductor layer 251, the high-concentration P type impurity region 210 is formed on the surface (that is, the interface with the impurity layer 205 or the impurity layer 255) opposite to the circuit portion 300. The high-concentration P type impurity region 210 is formed as a region where a maximum value of a boron concentration is lower than 1×10¹⁹ [atoms/cm³] within a depth range of 100 nm from the interface with the impurity layer 205 or the impurity layer 255.

The high-concentration P type impurity region 210 is formed before the imaging element is cut out as the chip. For example, when forming P type impurity layers corresponding to the high-concentration P type impurity layer 205 and the high-concentration P type impurity layer 255 on the wafer, a P type impurity is formed in the vicinity of the interface with the P type impurity layer by diffusing into the first semiconductor layer 201 and the first semiconductor layer 251.

The high-concentration P type impurity region 210 is a region formed by diffusion of the P type impurity in a process of forming the P type impurity layer, and thus has a P type impurity concentration lower than those of the impurity layer 205 and the impurity layer 255. On the other hand, in the first semiconductor layer 201 and the first semiconductor layer 251, a range in which a depth from the surface opposite to the circuit portion 300 is 100 nm or less is referred to as the high-concentration P type impurity region 210 for convenience because the P type impurity concentration is higher than that in a region where the depth exceeds 100 nm.

In the wafer stage before the imaging element 200 is cut out as the chip, thicknesses of layers corresponding to the first semiconductor layer 201, the interlayer wiring film 202, the wiring layer 203, and the metal layer 204 are controlled with extremely high accuracy. Similarly, inthe wafer stage before the imaging element 250 is cut out as the chip, thicknesses of layers corresponding to the first semiconductor layer 251, the interlayer wiring film 252, a wiring layer 253, and the metal layer 254 are controlled with extremely high accuracy. Therefore, after the circuit portion 300 and the imaging element 200, and the circuit portion 300 and the imaging element 250 are bonded, a distance from a main surface of the circuit portion 300 (wafer) to the high-concentration P type impurity region 210 of each imaging element (each chip) is extremely uniform. In other words, the high-concentration P type impurity region 210 of each imaging element (each chip) is disposed along a plane parallel to the main surface of the circuit portion 300.

On the other hand, the thickness of the semiconductor layer 206 and the thickness of the semiconductor layer 256 vary as described above. Therefore, a height H1 from the main surface of the circuit portion 300 (wafer) to an upper surface of the chip of the imaging element 200 and a height H2 from the main surface of the circuit portion 300 (wafer) to an upper surface of the chip of the imaging element 250 after bonding have variations.

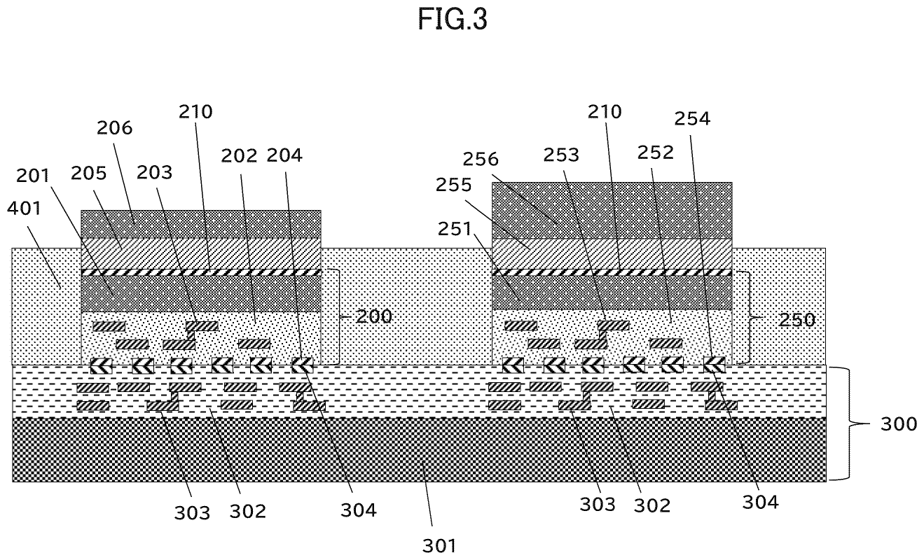

After bonding the wafer and the plurality of chips, for example, the silicon oxide 401 is deposited around the chips as illustrated in FIG. 3. That is, after the imaging element 200 (chip) and the imaging element 250 (chip) are bonded to the circuit portion 300 (wafer), for example, silicon oxide is deposited in a gap between the chips on the wafer. In a case where silicon oxide is also deposited on the imaging element 200 and the imaging element 250 when forming the silicon oxide 401, it is preferable to remove the silicon oxide from the top of the imaging element by using a technique such as back grinding (BG), the CMP, or wet etching to achieve the state illustrated in FIG. 3.

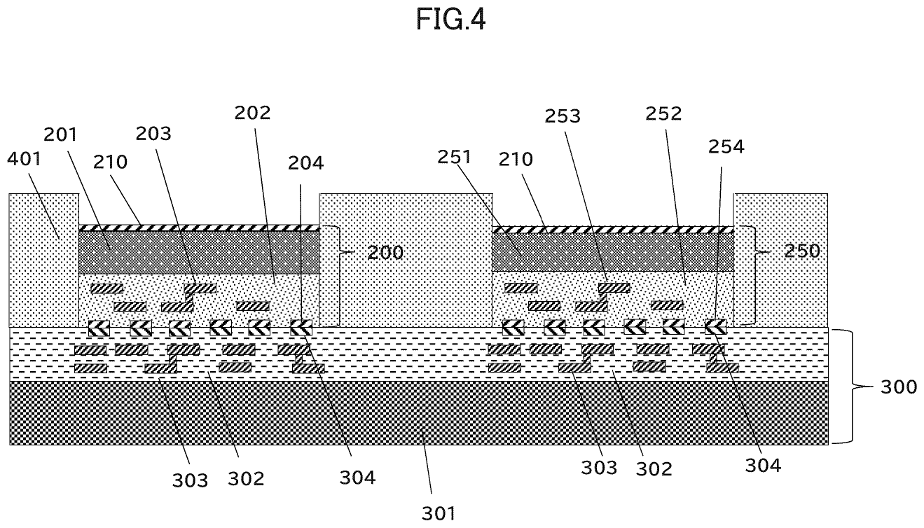

After the silicon oxide 401 is deposited, the semiconductor layer 206 and the impurity layer 205 attached to the imaging element 200, and the semiconductor layer 256 and the impurity layer 255 attached to the imaging element 250 are removed as illustrated in FIG. 4. First, for example, the semiconductor layer 206 and the semiconductor layer 256, which are N type semiconductor layers, are removed, and then the impurity layer 205 and the impurity layer 255 are removed.

When removing the impurity layer 205 and the impurity layer 255, a selective etching technique in which an etching speed (etching rate) varies depending on an impurity concentration is used. The impurity layer 205 and the impurity layer 255 are P+ type (or P++ type) impurity regions having a relatively higher P type impurity concentration than the high-concentration P type impurity region 210. Therefore, an etching condition is controlled such that the impurity layer 205 and the impurity layer 255, which are P+ type (or P++ type) impurity regions, are selectively removed, and etching substantially stops in the high-concentration P type impurity region 210 having a relatively lower P type impurity concentration than the impurity layer 205 and the impurity layer 255. That is, selective etching in which etching substantially stops in the high-concentration P type impurity region 210 provided in the first semiconductor layer 201 and the first semiconductor layer 251, which are P− type or N− type impurity regions, is performed. As a result, the high-concentration P type impurity region 210 remains near the surfaces of the first semiconductor layer 201 and the first semiconductor layer 251 after the selective etching.

Specifically, for example, a mixed solution of hydrofluoric acid (HF), nitric acid (HNO₃), and acetic acid (CH₃COOH) can be used as an etchant for wet etching. Wet etching processing conditions can be set as follows, for example. A temperature of a chemical solution is 20° C. to 30° C. In the chemical solution, a mixing ratio of hydrofluoric acid (HF), nitric acid (HNO₃), and acetic acid (CH₃COOH) is set to satisfy the following Condition 1.

$$HF < {HNO}_{3} < {CH}_{3} COOH \qquad Condition 1$$

According to the etching condition, it is possible to selectively etch only an impurity region whose P type impurity concentration is 1×10¹⁹ [atoms/cm³] or more. As a result, in both the imaging element 200 and the imaging element 250 bonded to the circuit portion 300, the high-concentration P type impurity region 210 forms the uppermost surface, and heights from bonding surfaces of both chips become extremely uniform.

In this example, the silicon oxide 401 is deposited between the bonded chips in advance, and then the film attached to the chip is removed. However, the silicon oxide 401 may also be deposited between the chips after first aligning the heights of the chips using the BG, the CMP, the wet etching, and the above-described selective etching by the wet etching.

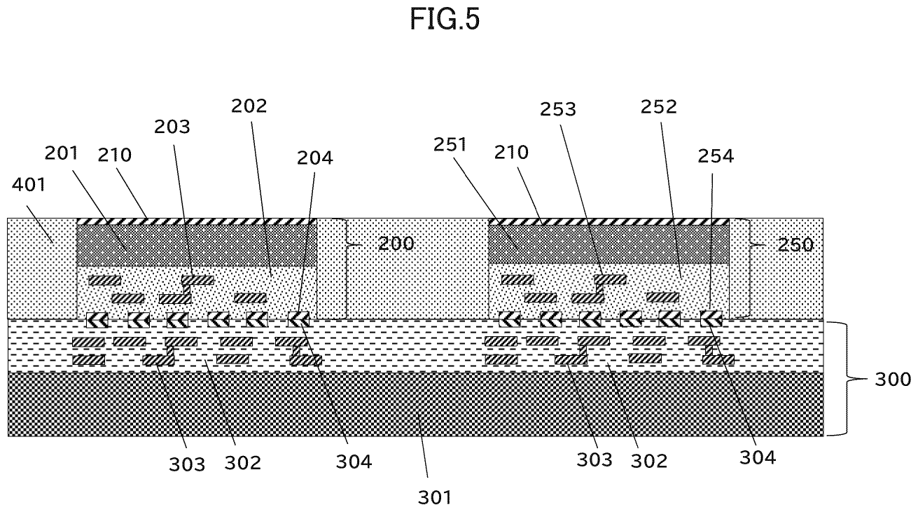

Next, by performing the CMP or additional wet etching, flatness of light receiving surfaces of the imaging element 200 and the imaging element 250 is improved as illustrated in FIG. 5. That is, a planarization step of aligning heights of an upper surface of the silicon oxide 401 and upper surfaces of the high-concentration P type impurity regions 210 of both chips for planarization is performed. Subsequently, the optical structures such as the color filter 402 and the microlens 403 are formed on the light receiving surfaces of the imaging element 200 and the imaging element 250.

According to the present embodiment, the light receiving surfaces of the plurality of imaging elements bonded to the circuit portion 300 are extremely flat, and the height from the bonding surface with the circuit portion to the light receiving surface of the imaging element hardly varies between the imaging elements. As a result, it is possible to reduce a variation in photoelectric conversion characteristic such as sensitivity of each imaging element. Furthermore, in each imaging element, the high-concentration P type impurity region 210 is disposed at the interface with the optical structure in the semiconductor layer serving as the light receiving surface, and thus, the influence of noise (for example, a dark current) can be reduced.

After bonding the plurality of imaging elements (chips) to the circuit portion 300 (wafer), a portion corresponding to each imaging element is cut out by dicing to form an individual piece, so that a plurality of semiconductor apparatuses 100 illustrated in FIG. 1 can be manufactured. In this case, the semiconductor apparatus 100 formed as the individual piece has an extremely small variation in photoelectric conversion characteristic, and the influence of noise (for example, a dark current and a leakage current) is reduced.

Furthermore, in a case where a semiconductor apparatus is configured in a state in which a plurality of imaging elements (chips) are bonded to a circuit portion (wafer) without dicing, it is possible to provide a semiconductor apparatus with extremely uniform imaging characteristics of the plurality of imaging elements mounted on the circuit portion and less influence of noise.

### Second Embodiment

### Configuration of Semiconductor Apparatus

A semiconductor apparatus according to a second embodiment will be described with reference to the drawings. A description of matters common to the first embodiment will be simplified or omitted. For the semiconductor apparatus according to the present embodiment, similarly to the first embodiment, a schematic cross-sectional view illustrating a cross section taken in a direction perpendicular to a main surface of a semiconductor substrate is as illustrated in FIG. 1. The semiconductor apparatus according to the present embodiment is a back-illuminated stacked sensor using a chip on wafer (CoW) technology, and an imaging element 200 and a circuit portion 300 are bonded to form an integrated structure.

### Method for Manufacturing Semiconductor Apparatus

The present embodiment is different from the first embodiment in that a chip-shaped imaging element and a dummy chip (dummy substrate) are bonded to the circuit portion 300 in a wafer state in a manufacturing process. The dummy chip (dummy substrate) is a chip that does not function as an electric circuit in the completed semiconductor apparatus.

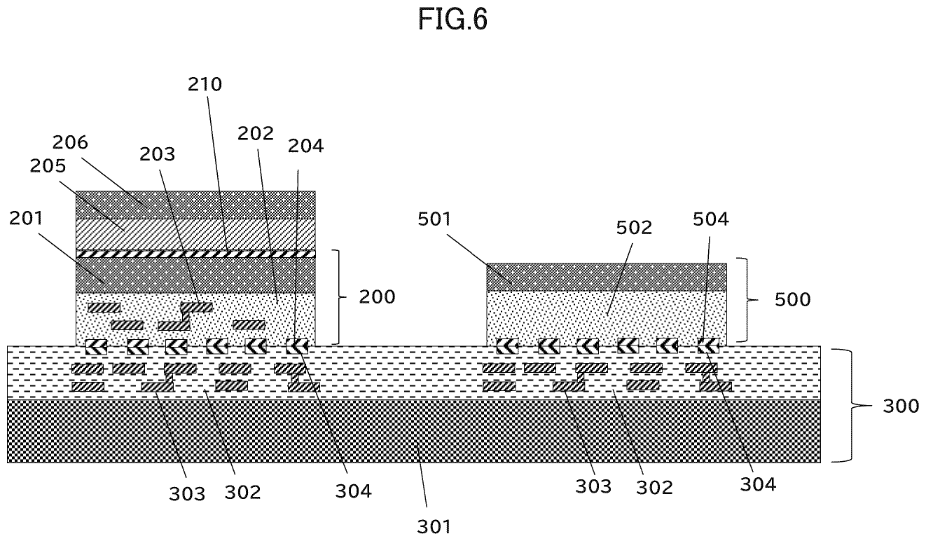

First, as illustrated in FIG. 6, the chip-shaped imaging element 200 and a dummy chip 500 are bonded to the circuit portion 300 in the wafer state. The dummy chip 500 is bonded to the circuit portion 300 in order to improve flatness of a stacked structure in a CoW structure. The dummy chip 500 includes a semiconductor layer 501 and an interlayer film 502. The circuit portion 300 and the imaging element 200 are bonded by metal bonding of Cu—Cu between metal layers and covalent bonding between an interlayer wiring film 202 and an interlayer wiring film 302. The circuit portion 300 and the dummy chip 500 are bonded by metal bonding of Cu—Cu between metal layers and covalent bonding between the interlayer film 502 and the interlayer wiring film 302. As a diffusion prevention structure made of, for example, silicon nitride is formed in a part of the interlayer wiring film 202 and the interlayer wiring film 302, it is possible to suppress diffusion of metal elements contained in a metal layer 304 and a metal layer 204.

Here, the chip-shaped imaging element 200 that is bonded is obtained by integrally forming a plurality of imaging elements on a semiconductor wafer and then cutting out the imaging element as a chip by dicing. The imaging element 200 is attached with a layer that is not necessary to finally function as an imaging element but is necessary in a process up to manufacturing. For example, an impurity layer 205 and a semiconductor layer 206 are attached to the chip of the imaging element 200. The semiconductor layer 206 attached to the chip of the imaging element 200 is, for example, an N type semiconductor substrate. Alternatively, the semiconductor layer 206 may be P type semiconductor substrates.

The impurity layer 205 attached to the chip of the imaging element 200 is a P+ type impurity region, and is a high-concentration P type impurity layer having an impurity concentration of 1×10¹⁹ [atoms/cm³] or more, for example.

The impurity layer 205, which is the high-concentration P type impurity layer, is formed before the imaging element is cut out as the chip, and there are various formation methods. Examples of a first method include a method of forming the high-concentration P type impurity layer 205 by epitaxial growth before forming a transistor or the like in a first semiconductor layer. Examples of a second method include a method of forming the high-concentration P type impurity layer 205 by impurity implantation. As the formation is performed with such methods, a thickness of the impurity layer 205 of each chip after being cut out can be made extremely approximated.

A first semiconductor layer 201 of the imaging element 200 and the semiconductor layer 501 of the dummy chip 500 are, for example, N type epi layers. A thickness of the semiconductor layer 501 may be smaller than a thickness of the first semiconductor layer 201. The first semiconductor layer 201 includes a device formation region where a photodiode, a transistor, and the like are formed. In the first semiconductor layer 201, a high-concentration P type impurity region 210 is formed on a surface (that is, an interface with the impurity layer 205) opposite to the circuit portion 300. The high-concentration P type impurity region 210 is formed as a region where a maximum value of a boron concentration is lower than 1×10¹⁹ [atoms/cm³] within a depth range of 100 nm from the interface with the impurity layer 205.

The high-concentration P type impurity region 210 is formed before the imaging element is cut out as the chip. For example, when forming a P type impurity layer corresponding to the high-concentration P type impurity layer 205 on the wafer, the high-concentration P type impurity region 210 is formed in the vicinity of the interface with the P type impurity layer 205 by diffusing P type impurity into the first semiconductor layer 201. The high-concentration P type impurity region 210 is a region formed by diffusion of the P type impurity in a process of forming the P type impurity layer, and thus has a P type impurity concentration lower than that of the impurity layer 205. On the other hand, in the first semiconductor layer 201, a range in which a depth from the surface opposite to the circuit portion 300 is 100 nm or less is referred to as the high-concentration P type impurity region 210 for convenience because the P type impurity concentration is higher than that in a region where the depth exceeds 100 nm.

After bonding the wafer and the plurality of chips, for example, silicon oxide 401 is deposited around the chips. That is, after the imaging element 200 (chip) and the dummy chip 500 (chip) are bonded to the circuit portion 300 (wafer), for example, silicon oxide is deposited in a gap between the chips on the wafer.

In a case where silicon oxide is also deposited on the imaging element 200 when forming the silicon oxide 401, it is desirable to remove the silicon oxide from the top of the imaging element by using a technique such as BG, CMP, or wet etching. At this time, the silicon oxide 401 on the dummy chip 500 is not necessarily removed.

After the silicon oxide 401 is deposited, the semiconductor layer 206 and the impurity layer 205 attached to the imaging element 200 are removed. First, the semiconductor layer 206, which is, for example, an N type semiconductor layer, is removed, and then the impurity layer 205 is removed.

When removing the impurity layer 205, a selective etching technique in which an etching speed varies depending on an impurity concentration is used. An etching condition is controlled such that the impurity layer 205, which is a P+ type (or P++ type) impurity region, is selectively removed, and etching stops in the P type impurity region 210 having a lower P type impurity concentration than the impurity layer 205. That is, selective etching in which etching substantially stops in the P type impurity region 210 provided in the first semiconductor layer 201, which is a P− type or N− type impurity region, is performed. As a result, the P type impurity region 210 remains near the surface of the first semiconductor layer 201 after the selective etching.

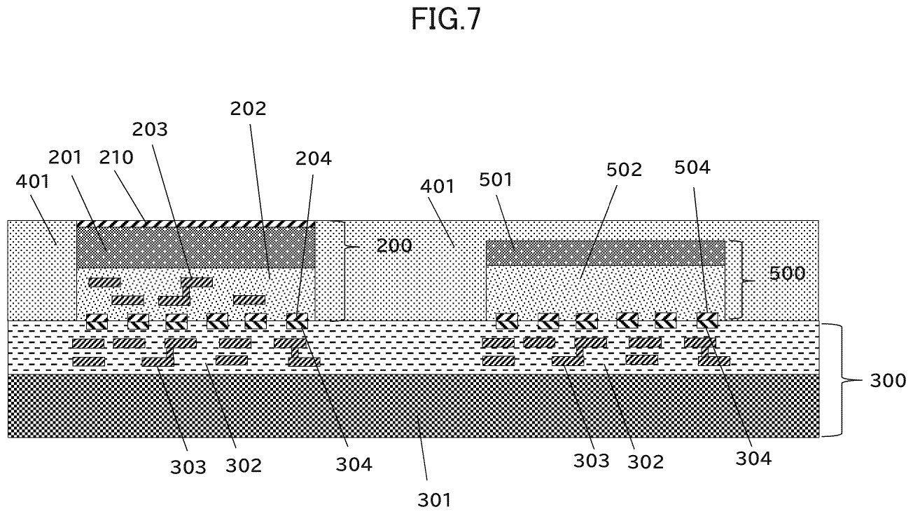

Thereafter, by performing the CMP or additional wet etching, flatness of a light receiving surface of the imaging element 200 can be improved as illustrated in FIG. 7. Subsequently, optical structures such as a color filter 402 and a microlens 403 are formed on the light receiving surface of the imaging element 200.

According to the present embodiment, the light receiving surface of the imaging element bonded to the circuit portion 300 becomes extremely flat, and a variation in photoelectric conversion characteristic such as sensitivity of the imaging element can be reduced. Furthermore, in the imaging element, the high-concentration P type impurity region 210 is disposed at an interface with the optical structure in the semiconductor layer serving as the light receiving surface, and thus, an influence of noise (for example, a dark current) can be reduced.

After bonding the plurality of imaging elements (chips) and the dummy chip to the circuit portion 300 (wafer), a portion corresponding to each imaging element is cut out by dicing to form an individual piece, so that the plurality of semiconductor apparatuses 100 illustrated in FIG. 1 can be manufactured. In this case, the semiconductor apparatus 100 formed as the individual piece has an extremely small variation in photoelectric conversion characteristic, and the influence of noise (for example, a dark current and a leakage current) is reduced.

Furthermore, in a case where a semiconductor apparatus is configured in a state in which an imaging element (chip) and a dummy chip are bonded to the circuit portion 300 (wafer), it is possible to provide a semiconductor apparatus with extremely uniform imaging characteristics of the mounted imaging element and less influence of noise.

### Third Embodiment

### Configuration of Semiconductor Apparatus

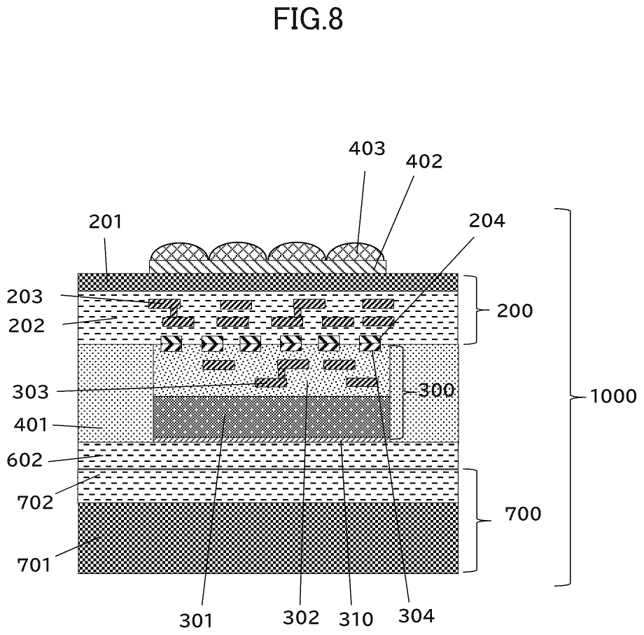

A semiconductor apparatus according to a third embodiment will be described with reference to the drawings. FIG. 8 is a schematic cross-sectional view illustrating a cross section of a semiconductor apparatus 1000 according to the present embodiment taken in a direction perpendicular to a main surface of a semiconductor substrate.

The semiconductor apparatus 1000 is a back-illuminated stacked sensor using a chip on wafer (CoW) technology, and an imaging element 200, a circuit portion 300, and a support substrate 700 are bonded to form an integrated structure. The support substrate 700 includes a semiconductor layer 701 and a bonding layer 702.

In the first embodiment, the semiconductor apparatus 100 has a configuration in which the imaging element 200 (chip) having a small area is bonded to the circuit portion 300 (wafer) having a large area in plan view. On the other hand, in the present embodiment, the semiconductor apparatus 1000 has a configuration in which the circuit portion 300 (chip) having a small area is bonded to the imaging element 200 (wafer) having a large area in plan view.

The imaging element 200 includes a first semiconductor layer 201, an interlayer wiring film 202 (interlayer insulating film), and a wiring layer 203. A photodiode (not illustrated) serving as a photoelectric conversion unit is formed in the first semiconductor layer 201, and the interlayer wiring film 202 and the wiring layer 203 are stacked under the first semiconductor layer 201. A metal layer 204 electrically connected to the wiring layer 203 is disposed on a lower surface (a surface opposite to the first semiconductor layer 201) of the interlayer wiring film 202. The metal layer 204 contains, for example, copper as a main component, and the interlayer wiring film 202 contains, for example, silicon oxide as a main component. Optical structures such as a color filter 402 and a microlens 403 are disposed on a light receiving surface side (an upper side in FIG. 8) of the imaging element 200. It is also possible to form, for example, a dielectric layer having a fixed charge, a light shielding structure, or a light guiding structure between the light receiving surface side (opposite to the circuit portion 300) of the imaging element 200 and the color filter 402.

When seeing through the semiconductor apparatus 1000 through from a direction perpendicular to a main surface of the first semiconductor layer 201, silicon oxide 401 is formed in contact with a side surface of the circuit portion 300 so as to surround the circuit portion 300.

The circuit portion 300 includes a second semiconductor layer 301, an interlayer wiring film 302 (interlayer insulating film), and a wiring layer 303. The circuit portion 300 includes at least some of a drive circuit that drives the imaging element 200 to read a signal, a control circuit, a signal processing circuit, an output circuit, and the like. A metal layer 304 electrically connected to the wiring layer 303 is disposed on an upper surface (a surface adjacent to the imaging element 200) of the interlayer wiring film 302. The metal layer 304 contains, for example, copper as a main component, and the interlayer wiring film 302 contains, for example, silicon oxide as a main component. The second semiconductor layer 301 includes a high-concentration P type impurity region 310 on the outermost surface adjacent to the support substrate 700 (opposite to the imaging element 200). As the second semiconductor layer 301 includes the high-concentration P type impurity region 310, it is possible to reduce an influence of noise such as a leakage current from an interface of the circuit portion 300.

The imaging element 200 and the circuit portion 300 are bonded to each other. That is, the metal layer 204 and the metal layer 304 are bonded by metal bonding of Cu—Cu, and the interlayer wiring film 202 and the interlayer wiring film 302 are bonded by covalent bonding of silicon oxide. As the metal layer 204 and the metal layer 304 are bonded to each other, a wiring included in the imaging element 200 and a wiring included in the circuit portion 300 are electrically connected to form an electric circuit network of the semiconductor apparatus 1000.

If the imaging element 200 is referred to as a wafer and the circuit portion 300 is referred to as a chip, a chip on wafer (CoW) structure in which the chip is disposed on the wafer having a relatively large area in plan view is formed. In other words, the chip having a relatively small area in plan view is stacked on a main surface of the wafer, and the chip forms a protrusion protruding from the main surface of the wafer.

In the present embodiment having such a structure, the high-concentration P type impurity region 310 is provided at the interface of the circuit portion 300 as the chip, so that a pinning effect can be obtained, and the influence of noise (for example, a leakage current) can be reduced.

### Method for Manufacturing Semiconductor Apparatus

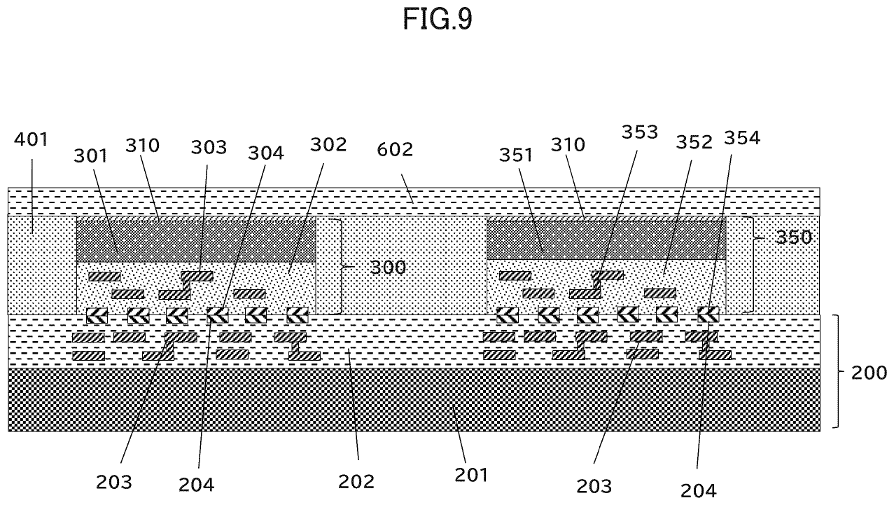

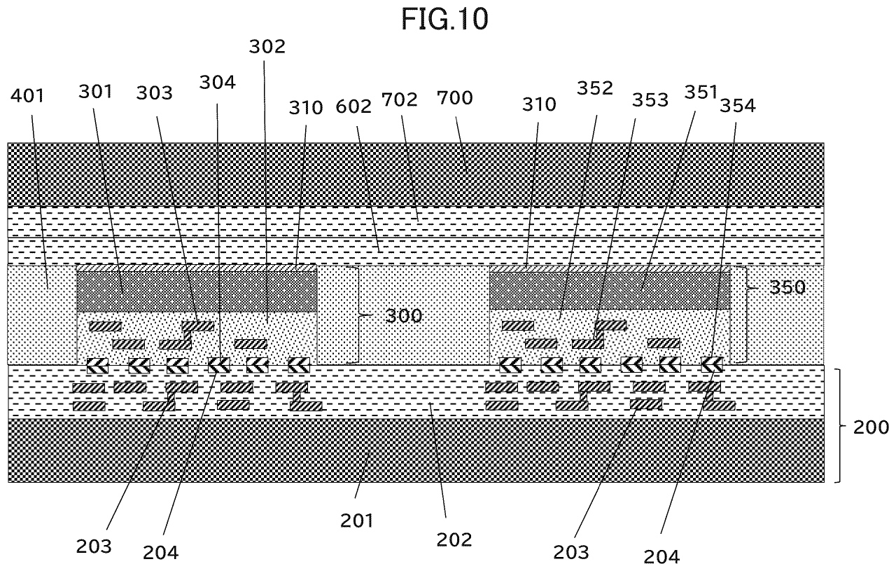

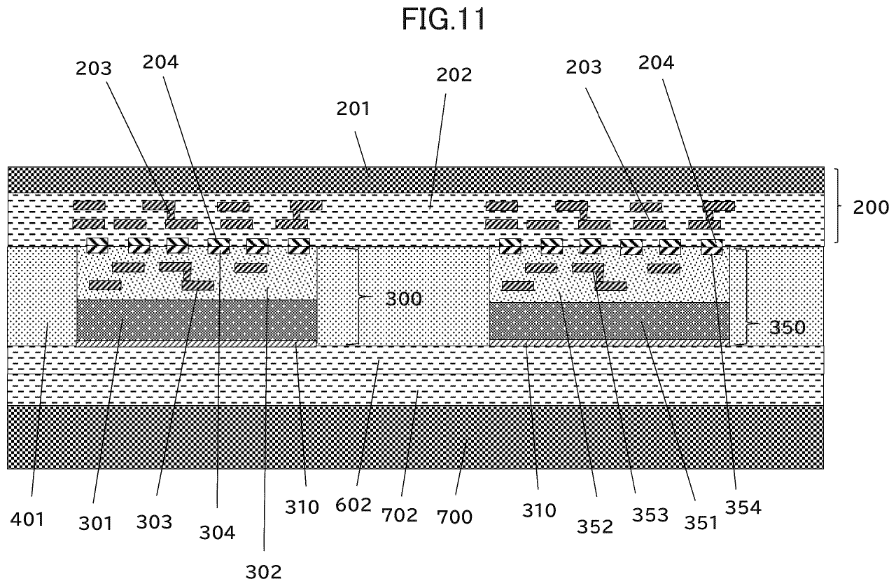

Next, a method for manufacturing the semiconductor apparatus 1000 according to the present embodiment will be described with reference to FIGS. 9 to 11. FIGS. 9 to 11 are schematic cross-sectional views each illustrating a state in each stage of a manufacturing process, taken in a direction perpendicular to the main surface of the first semiconductor layer 201. FIGS. 9 and 10 are illustrated in an inverted orientation relative to FIG. 8, and FIG. 11 is illustrated in the same orientation as FIG. 8.

First, as illustrated in FIG. 9, the circuit portion 300 and a circuit portion 350 having a chip shape are bonded to the imaging element 200 in a wafer state in which a plurality of imaging portions are formed. The circuit portion 350 includes a second semiconductor layer 351, an interlayer wiring film 352 (interlayer insulating film), a wiring layer 353, and a metal layer 354.

For example, the metal layer 204 mainly containing Cu is disposed in the imaging element 200, the metal layer 304 mainly containing Cu is disposed in the circuit portion 300, and the metal layer 354 mainly containing Cu is disposed in the circuit portion 350. The metal layer 204 is electrically connected to the wiring layer 203, the metal layer 304 is electrically connected to the wiring layer 303, and the metal layer 354 is electrically connected to the wiring layer 353.

The circuit portion 300 and the imaging element 200 are bonded by metal bonding of Cu—Cu between metal layers and covalent bonding between an interlayer wiring film 202 and an interlayer wiring film 302. The circuit portion 350 and the imaging element 200 are bonded by metal bonding of Cu—Cu between the metal layers and covalent bonding between the interlayer wiring film 202 and the interlayer wiring film 352. As a diffusion prevention structure made of, for example, silicon nitride is formed in a part of the interlayer wiring film 202, the interlayer wiring film 302, and the interlayer wiring film 352, it is possible to suppress diffusion of metal elements contained in the metal layer 304, the metal layer 204, and the metal layer 354.

When the circuit portion 300 and the circuit portion 350 having the chip shape are bonded to the imaging element 200, selective etching is performed using the high-concentration P type impurity region 310 as an etch stop layer by a planarization technique similar to that described in the first embodiment, so that both chip surfaces are planarized. Thereafter, the entire surface is further planarized by performing CMP or additional wet etching. As a result, flatness of the semiconductor layers of the circuit portion 300 and the circuit portion 350 can be improved. In addition, by leaving the high-concentration P type impurity region 310 on the thinned surface, the leakage current from the interface between the circuit portion 300 and the circuit portion 350 can be reduced, so that a photoelectric conversion apparatus with suppressed power consumption can be manufactured. Thereafter, a bonding layer 602 is formed on the planarized surface of the wafer. In addition, a bonding layer 702 is separately formed on the support substrate 700 (not illustrated in FIG. 9).

Next, as illustrated in FIG. 10, the bonding layer 602 formed on the wafer and the bonding layer 702 formed on the support substrate 700 are bonded. For example, a silicon oxide film, carbon-containing silicon nitride (SiCN), or the like can be used for the bonding layer 602 and the bonding layer 702. In the present embodiment, the semiconductor layers of the circuit portion 300 and the circuit portion 350 are uniformly planarized over the entire surface of the wafer, and thus, a bonding failure can be reduced.

Thereafter, as illustrated in FIG. 11, the first semiconductor layer 201 of the imaging element 200 is thinned as appropriate.

Then, the optical structures such as the color filter 402 and the microlens 403 are formed on the first semiconductor layer 201.

In this way, after bonding a plurality of circuit portions (chips) to a wafer on which a plurality of imaging elements are formed, a portion corresponding to each imaging element is cut out by dicing to form an individual piece, so that a plurality of semiconductor apparatuses 1000 illustrated in FIG. 8 can be manufactured. In this case, the semiconductor apparatus 1000 formed as the individual piece has an extremely small variation in photoelectric conversion characteristic, and the influence of noise (for example, a leakage current) is reduced.

Furthermore, in a case where a semiconductor apparatus is configured in a state in which a plurality of circuit portions (chips) are bonded to an imaging element (wafer) without dicing, it is possible to provide a semiconductor apparatus with less influence of noise of each mounted circuit portion.

For example, the circuit portion 300 may be a substrate on which a driving transistor for driving the imaging element is disposed, the support substrate 700 may be a circuit substrate, and the driving transistor substrate and the circuit substrate may be electrically connected.

### Fourth Embodiment

### Configuration of Semiconductor Apparatus

A semiconductor apparatus according to a fourth embodiment will be described with reference to the drawings. A description of matters common to the first embodiment will be simplified or omitted. For the semiconductor apparatus according to the present embodiment, similarly to the first embodiment, a schematic cross-sectional view illustrating a cross section taken in a direction perpendicular to a main surface of a semiconductor substrate is as illustrated in FIG. 1. The semiconductor apparatus according to the present embodiment is a back-illuminated stacked sensor using a chip on wafer (CoW) technology, and an imaging element 200 and a circuit portion 300 are bonded to form an integrated structure.

### Method for Manufacturing Semiconductor Apparatus

The present embodiment is different from the first embodiment in that a chip-shaped imaging element and a dummy chip are bonded to the circuit portion 300 in a wafer state in a manufacturing process. The dummy chip (dummy substrate) is a chip that does not function as an electric circuit in the completed semiconductor apparatus.

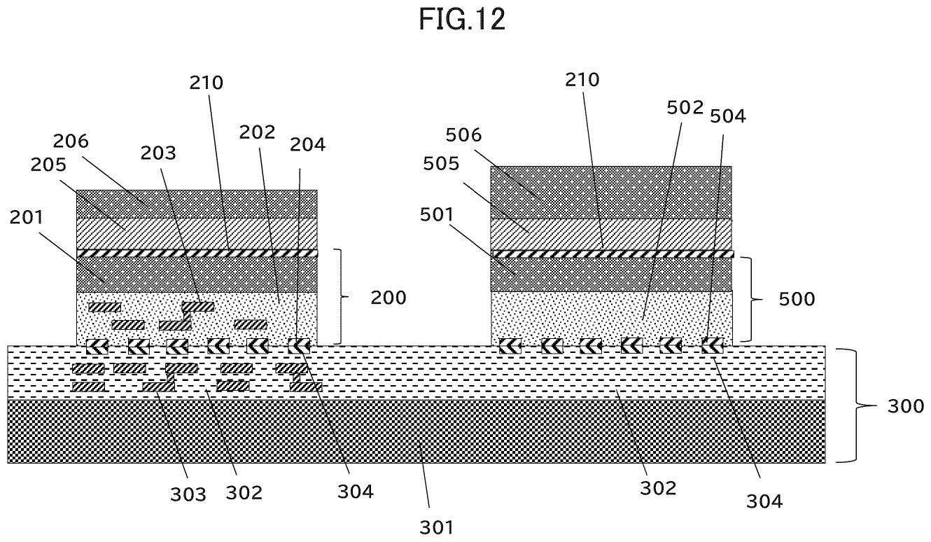

First, as illustrated in FIG. 12, the chip-shaped imaging element 200 and a dummy chip 500 are bonded to the circuit portion 300 in a wafer state. The dummy chip 500 is bonded to the circuit portion 300 in order to improve flatness of a stacked structure in a CoW structure. The dummy chip 500 is disposed in a region where no circuit is formed as illustrated in the circuit portion 300 in the wafer state, and may also be disposed in a region where any circuit or wiring is formed.

The dummy chip 500 includes a semiconductor layer 501 and an interlayer film 502. The semiconductor layer 501 is a semiconductor layer having a similar conductivity type and a similar impurity concentration as those of a first semiconductor layer 201 of the imaging element 200. In the semiconductor layer 501, a transistor, a diode, or the like is not formed, but may be formed in some cases.

A high-concentration P type impurity region 210 is formed on an interface of the semiconductor layer 501 opposite to the circuit portion 300, similarly to the first semiconductor layer 201 of the imaging element 200. That is, the high-concentration P type impurity region 210 is formed as a region where a maximum value of a boron concentration is lower than 1×10¹⁹ [atoms/cm³] within a depth range of 100 nm from an interface with an impurity layer 505 in the dummy chip 500.

The interlayer film 502 of the dummy chip 500 is made of a similar material to that of an interlayer wiring film 202 of the imaging element 200. In the illustrated example, a wiring layer is not provided in the interlayer film 502 of the dummy chip 500, but a dummy wiring may be provided. A metal layer 504 for metal bonding with a metal layer 304 of the circuit portion 300 is disposed on the interlayer film 502.

The impurity layer 505 and a semiconductor layer 506 are attached to the dummy chip 500. The impurity layer 505 is a layer similar to an impurity layer 205 attached to the imaging element 200, and the semiconductor layer 506 is a layer similar to a semiconductor layer 206 attached to the imaging element 200.

The circuit portion 300 and the imaging element 200 are bonded by metal bonding of Cu—Cu between metal layers and covalent bonding between an interlayer wiring film 202 and an interlayer wiring film 302. The circuit portion 300 and the dummy chip 500 are bonded by metal bonding of Cu—Cu between the metal layers and covalent bonding between the interlayer film 502 and the interlayer wiring film 302. As a diffusion prevention structure made of, for example, silicon nitride is formed in a part of the interlayer wiring film 202 and the interlayer wiring film 302, it is possible to suppress diffusion of metal elements contained in a metal layer 304 and a metal layer 204.

Here, the chip-shaped imaging element 200 that is bonded is integrally formed on a semiconductor wafer and then cutout as a chip by dicing. The imaging element 200 is attached with a layer that is not necessary to finally function as an imaging element but is necessary in a process up to manufacturing. For example, the impurity layer 205 and the semiconductor layer 206 are attached to the chip of the imaging element 200. The semiconductor layer 206 attached to the chip of the imaging element 200 is, for example, an N type semiconductor substrate. Alternatively, the semiconductor layer 206 may be P type semiconductor substrates.

The impurity layer 205 attached to the chip of the imaging element 200 is a P+ type impurity region, and is a high-concentration P type impurity layer having an impurity concentration of 1×10¹⁹ [atoms/cm³] or more, for example.

The impurity layer 205, which is the high-concentration P type impurity layer, is formed before the imaging element is cut out as the chip, but there are various formation methods. Examples of a first method include a method of forming the high-concentration P type impurity layer 205 by epitaxial growth before forming a transistor or the like in a first semiconductor layer. Examples of a second method include a method of forming the high-concentration P type impurity layer 205 by impurity implantation. As the formation is performed with such methods, a thickness of the impurity layer 205 of each chip after being cut out can be extremely approximated.

The first semiconductor layer 201 of the imaging element 200 and the semiconductor layer 501 of the dummy chip 500 are, for example, N type epi layers. A thickness of the semiconductor layer 501 is similar to a thickness of the first semiconductor layer 201. The first semiconductor layer 201 includes a device formation region where a photodiode, a transistor, and the like are formed. In the first semiconductor layer 201, the high-concentration P type impurity region 210 is formed on a surface (that is, an interface with the impurity layer 205) opposite to the circuit portion 300. The high-concentration P type impurity region 210 is formed as a region where a maximum value of a boron concentration is lower than 1×10¹⁹ [atoms/cm³] within a depth range of 100 nm from the interface with the impurity layer 205.

The high-concentration P type impurity region 210 is formed before the imaging element is cut out as the chip. For example, when forming a P type impurity layer corresponding to the high-concentration P type impurity layer 205 on the wafer, a P type impurity is formed in the vicinity of the interface with the P type impurity layer by diffusing into the first semiconductor layer 201. The high-concentration P type impurity region 210 is a region formed by diffusion of the P type impurity in a process of forming the P type impurity layer, and thus has a P type impurity concentration lower than that of the impurity layer 205. On the other hand, in the first semiconductor layer 201, a range in which a depth from the surface opposite to the circuit portion 300 is 100 nm or less is referred to as the high-concentration P type impurity region 210 for convenience because the P type impurity concentration is higher than that in a region where the depth exceeds 100 nm.

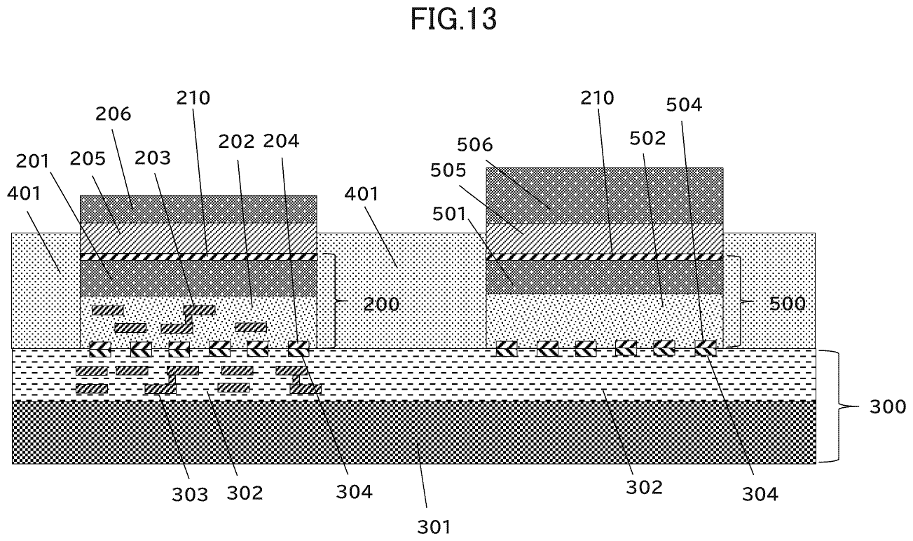

After bonding the wafer and the plurality of chips, for example, silicon oxide 401 is deposited around the chips as illustrated in FIG. 13. That is, after the imaging element 200 (chip) and the dummy chip 500 (chip) are bonded to the circuit portion 300 (wafer), for example, silicon oxide is deposited in a gap between the chips on the wafer.

At this time, in a case where silicon oxide is also deposited on the imaging element 200 and the dummy chip 500, it is desirable to remove the silicon oxide from the top of the imaging element and the dummy chip by using a technique such as BG, CMP, or wet etching.

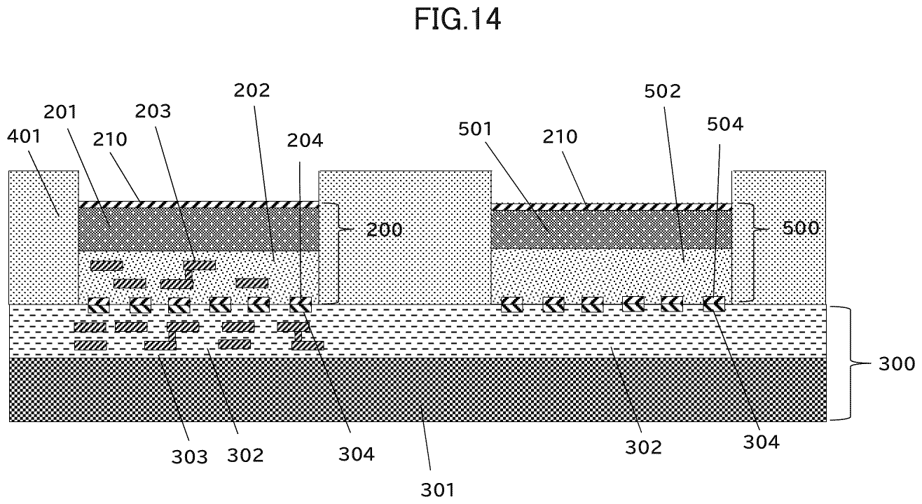

After the silicon oxide 401 is deposited, the semiconductor layer 206 and the impurity layer 205 attached to the imaging element 200 and the semiconductor layer 506 and the impurity layer 505 attached to the dummy chip 500 are removed as illustrated in FIG. 14.

When removing the impurity layer 205 and the impurity layer 505, a selective etching technique in which an etching speed varies depending on an impurity concentration is used. An etching condition is controlled such that the impurity layer 205 and the impurity layer 505, which are P+ type (or P++ type) impurity regions, are selectively removed, and etching stops in the P type impurity region 210 having a lower P type impurity concentration than the impurity layer 205 and the impurity layer 505. That is, selective etching stops in the P type impurity region 210 provided in the first semiconductor layer 201 and the semiconductor layer 501 which are P-type or N-type impurity regions. As a result, the P type impurity region 210 remains near the surfaces of the first semiconductor layer 201 and the semiconductor layer 501 after the selective etching.

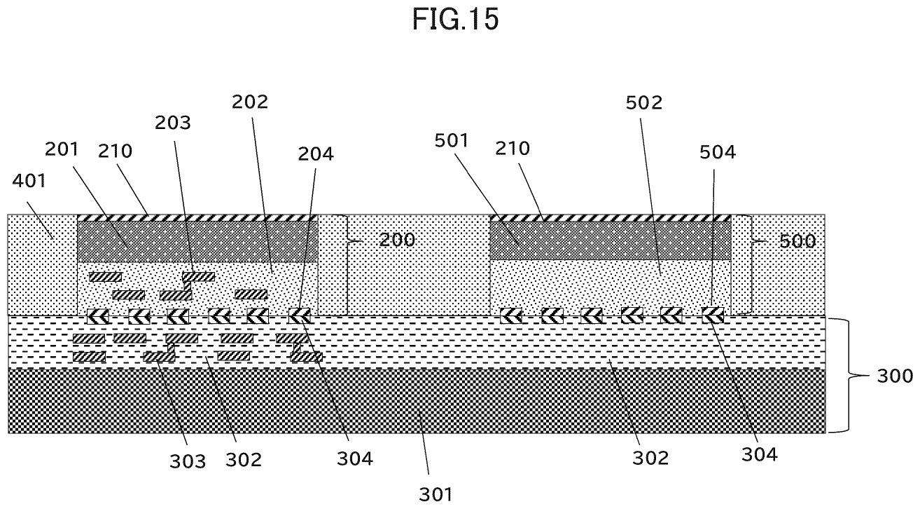

Thereafter, by performing the CMP or additional wet etching, flatness of a light receiving surface of the imaging element 200 can be improved as illustrated in FIG. 15. Subsequently, optical structures such as a color filter 402 and a microlens 403 are formed on the light receiving surface of the imaging element 200.

According to the present embodiment, the light receiving surface of the imaging element bonded to the circuit portion 300 becomes extremely flat, and a variation in photoelectric conversion characteristic such as sensitivity of the imaging element can be reduced. Furthermore, in the imaging element, the high-concentration P type impurity region 210 is disposed at an interface with the optical structure in the semiconductor layer serving as the light receiving surface, and thus, an influence of noise (for example, a dark current) can be reduced.

After bonding the plurality of imaging elements (chips) and the dummy chip to the circuit portion 300 (wafer), a portion corresponding to each imaging element is cut out by dicing to form an individual piece, so that the plurality of semiconductor apparatuses 100 illustrated in FIG. 1 can be manufactured. In this case, the semiconductor apparatus 100 formed as the individual piece has an extremely small variation in photoelectric conversion characteristic, and the influence of noise (for example, a dark current) is reduced.

Furthermore, in a case where a semiconductor apparatus is configured in a state in which an imaging element (chip) and a dummy chip are bonded to the circuit portion 300 (wafer), it is possible to provide a semiconductor apparatus with extremely uniform imaging characteristics of the mounted imaging element and less influence of noise.

### Fifth Embodiment

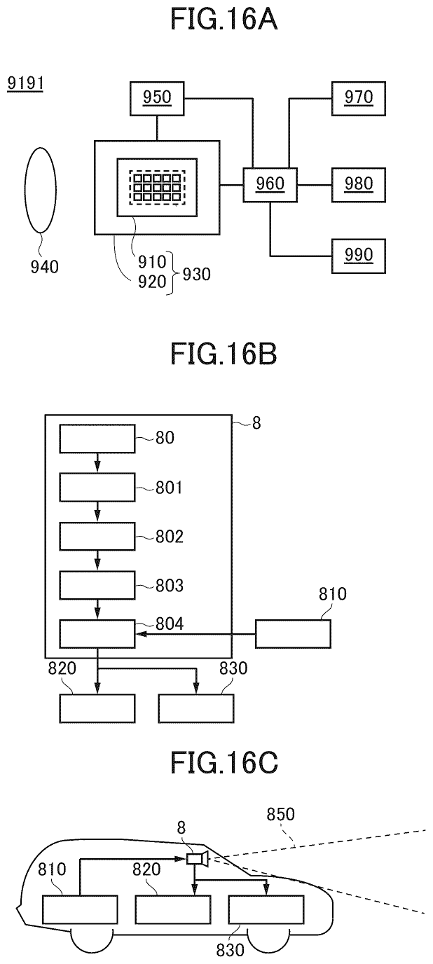

As a fifth embodiment, equipment including the semiconductor apparatus (solid-state imaging apparatus) according to any one of the above-described embodiments will be described. FIG. 16A is a schematic diagram for describing equipment 9191 including a semiconductor apparatus 930 according to the above-described embodiment. The equipment 9191 including the semiconductor apparatus 930 will be described in detail.

The semiconductor apparatus 930 includes a semiconductor device 910 in which a first chip serving as a photoelectric conversion apparatus and a second chip including at least one of a memory circuit and a logic circuit are integrated. In addition to the semiconductor device 910, the semiconductor apparatus 930 may further include a package 920 that houses the semiconductor device 910. The package 920 can include a base to which the semiconductor device 910 is fixed and a lid such as glass that faces the semiconductor device 910. The package 920 can further include a bonding member such as a bonding wire or a bump that connects a terminal provided on the base and a terminal provided on the semiconductor device 910.

The equipment 9191 can include at least one of an optical apparatus 940, a control apparatus 950, a processing apparatus 960, a display apparatus 970, a storage apparatus 980, and a mechanical apparatus 990. The optical apparatus 940 is, for example, a lens, a shutter, or a mirror provided corresponding to the semiconductor apparatus 930. The control apparatus 950 controls the semiconductor apparatus 930. The control apparatus 950 is, for example, a semiconductor apparatus such as an application specific integrated circuit (ASIC).

The processing apparatus 960 processes a signal output from the semiconductor apparatus 930. The processing apparatus 960 is a semiconductor apparatus such as a central processing unit (CPU) or an ASIC for configuring an analog front end (AFE) or a digital front end (DFE). The display apparatus 970 is an EL display apparatus or a liquid crystal display apparatus that displays information (image) obtained by the semiconductor apparatus 930. The storage apparatus 980 is a magnetic device or a semiconductor device that stores information (image) obtained by the semiconductor apparatus 930. The storage apparatus 980 is a volatile memory such as a static random-access memory (SRAM) or a dynamic random-access memory (DRAM), or a nonvolatile memory such as a flash memory or a hard disk drive.

The mechanical apparatus 990 includes a movable unit such as a motor or an engine, or a propulsion unit. In the equipment 9191, a signal output from the semiconductor apparatus 930 is displayed on the display apparatus 970 or is transmitted to the outside by a communication apparatus (not illustrated) included in the equipment 9191. Therefore, the equipment 9191 preferably further includes the storage apparatus 980 and the processing apparatus 960 separately from a storage circuit and an arithmetic circuit of the semiconductor apparatus 930. The mechanical apparatus 990 may be controlled based on a signal output from the semiconductor apparatus 930.

Furthermore, the equipment 9191 is suitable for electronic equipment such as an information terminal (for example, a smartphone or a wearable terminal) having an imaging function or a camera (for example, an interchangeable lens camera, a compact camera, a video camera, or a surveillance camera). The mechanical apparatus 990 in the camera can drive components of the optical apparatus 940 for zooming, focusing, and shutter operations. Alternatively, the mechanical apparatus 990 in the camera can move the semiconductor apparatus 930 for a vibration-proof operation.

Furthermore, the equipment 9191 may be transportation equipment such as a vehicle, a ship, or a flying body. The mechanical apparatus 990 in the transportation equipment can be used as a movement apparatus. The equipment 9191 serving as transportation equipment is suitable for transporting the semiconductor apparatus 930 and assisting and/or automating driving (steering) by the imaging function. The processing apparatus 960 for assisting and/or automating the driving (steering) can perform processing for operating the mechanical apparatus 990 serving as the movement apparatus based on information obtained by the semiconductor apparatus 930. Alternatively, the equipment 9191 may be medical equipment such as an endoscope, measurement equipment such as a distance measurement sensor, analytical equipment such as an electron microscope, office equipment such as a copying machine, or industrial equipment such as a robot. According to the above-described embodiment, since noise in the imaging element or the circuit portion is reduced, it is possible to stably acquire an image with favorable characteristics.

Therefore, if the semiconductor apparatus 930 according to the present embodiment is used for the equipment 9191, the value of the equipment can also be improved. For example, it is possible to obtain excellent performance when the semiconductor apparatus 930 is mounted on the transportation equipment and performs imaging of the outside of the transportation equipment or measurement of an external environment. Therefore, in manufacturing and selling the transportation equipment, it is advantageous to determine to mount the semiconductor apparatus according to the present embodiment on the transportation equipment in order to enhance the performance of the transportation equipment itself. In particular, the semiconductor apparatus 930 is suitable for transportation equipment that performs driving assistance and/or automated driving of the transportation equipment by using information obtained by the semiconductor apparatus. Implementation in a vehicle, a ship, a flying body, and the like is not limited to application to equipment practically used for transportation purposes, and can be suitably applied to, for example, a drone or the like that performs aerial imaging for various purposes including inspection of buildings and agricultural facilities, monitoring of natural phenomena, and the like.

A photoelectric conversion system and a mobile body according to the present embodiment will be described with reference to FIGS. 16B and 16C. FIG. 16B illustrates an example of the photoelectric conversion system related to an in-vehicle camera. A photoelectric conversion system 8 includes a photoelectric conversion apparatus 80. The photoelectric conversion apparatus 80 is a photoelectric conversion apparatus serving as an electronic component described in the above-described embodiment. The photoelectric conversion system 8 includes an image processing unit 801 that performs image processing on a plurality of pieces of image data acquired by the photoelectric conversion apparatus 80, and a parallax acquisition unit 802 that calculates a parallax (a phase difference of a parallax image) from the plurality of pieces of image data acquired by the photoelectric conversion system 8. Furthermore, the photoelectric conversion system 8 includes a distance acquisition unit 803 that calculates a distance to a target object based on the calculated parallax, and a collision determination unit 804 that determines whether or not there is a possibility of collision based on the calculated distance. Here, the parallax acquisition unit 802 and the distance acquisition unit 803 are examples of a distance information acquisition unit that acquires distance information to the target object. That is, the distance information is information regarding the parallax, a defocus amount, the distance to the target object, and the like. The collision determination unit 804 may determine the possibility of collision by using any one of these pieces of distance information. The distance information acquisition unit may be implemented by dedicated hardware or may be implemented by a software module. Alternatively, the distance information acquisition unit may be implemented by a field programmable gate array (FPGA), an application specific integrated circuit (ASIC), or the like.

The photoelectric conversion system 8 is connected to a vehicle information acquisition apparatus 810, and can acquire vehicle information such as a vehicle speed, a yaw rate, and a steering angle. In addition, the photoelectric conversion system 8 is connected to a control ECU 820 which is a control apparatus that outputs a control signal for generating a braking force on the vehicle based on a determination result of the collision determination unit 804. The photoelectric conversion system 8 is also connected to a warning apparatus 830 that issues a warning to a driver based on the determination result of the collision determination unit 804. For example, in a case where the determination result of the collision determination unit 804 indicates that the possibility of collision is high, the control ECU 820 performs vehicle control to avoid collision and reduce damage by applying a brake, returning an accelerator, reducing an engine output, or the like. The warning apparatus 830 issues a warning to a user by emitting warnings such as sound, displaying warning information on a screen of a car navigation system or the like, providing vibrations to a seat belt or a steering wheel, or the like.

In the present embodiment, the photoelectric conversion system 8 images the periphery of the vehicle, for example, an area in front of or behind the vehicle.

FIG. 16C illustrates the photoelectric conversion system in a case of imaging the area (imaging range 850) in front of the vehicle. The vehicle information acquisition apparatus 810 sends an instruction to the photoelectric conversion system 8 or the photoelectric conversion apparatus 80. With such a configuration, accuracy of distance measurement can be further improved.

In the above description, an example of performing control to prevent collision with another vehicle has been described, but the present technology is also applicable to control for performing automated driving following another vehicle, control for performing automated driving so as not to stray from a lane, and the like. Furthermore, the photoelectric conversion system is not limited to the vehicle such as an own vehicle, and can be applied to a mobile body (mobile apparatus) such as a ship, an aircraft, or an industrial robot, for example. In addition, the present technology can be applied not only to a mobile body but also to equipment that widely uses object recognition, such as an intelligent transport system (ITS). According to the above-described embodiment, it is possible to stably acquire an image having favorable characteristics.

### Other Embodiments

Note that the present invention is not limited to the embodiments described above, and many modifications can be made within the technical idea of the present invention. For example, all or some of the different embodiments described above may be combined and implemented.

For example, in the third embodiment, the semiconductor apparatus is manufactured by bonding the circuit portions 300 (chips) having a small area to the imaging element 200 (wafer) having a large area in plan view, but some of the plurality of chips may be dummy chips as in the second embodiment or the fourth embodiment.

In the semiconductor apparatus according to the present invention, the number of chips bonded to the largest semiconductor substrate in plan view may be one or any number of two or more. In the semiconductor apparatus, the largest semiconductor substrate in plan view may be the imaging element, and one or more circuit portions (chips) or dummy chips may be bonded to the substrate. Alternatively, in the semiconductor apparatus, the largest semiconductor substrate in plan view may be the circuit portion, and one or more imaging elements (chips) or dummy chips may be bonded to the substrate.

In the method for manufacturing a semiconductor apparatus according to the present invention, the number of chips bonded to one wafer in the manufacturing process is not limited to two, and a larger number of chips may be bonded. The circuit portion may be formed on the wafer, and the imaging elements (chips) or dummy chips may be bonded to the wafer in the manufacturing process. Alternatively, the imaging element may be formed on the wafer, and the circuit portions (chips) or dummy chips may be bonded to the wafer in the manufacturing process.

The semiconductor apparatus described in each embodiment is not limited to the photoelectric conversion apparatus for imaging. For example, the present technology is also applicable to a distance measurement apparatus (an apparatus for focus detection, distance measurement using time of flight (TOF), or the like), a photometric apparatus (an apparatus for measuring an incident light quantity or the like), or the like. The photoelectric conversion apparatus to which the present invention can be applied is not limited to a specific form, and for example, a portion of the imaging element may be any one of a front-illuminated type and a back-illuminated type.

The conductivity type of the semiconductor layer described in the embodiment is an example, and is not limited to only the conductivity type described in the embodiment. Even in a case where the conductivity type is changed from the conductivity type described in the embodiment, the present invention can be implemented by using an etchant by which a predetermined layer is etched and for which another predetermined layer functions as an etch stopper.

According to the present disclosure, in a case where a plurality of semiconductor chips are bonded to a wafer, it is possible to suppress a variation in height between the bonded semiconductor chips.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-050285, filed Mar. 26, 2024, which is hereby incorporated by reference herein in its entirety.

What is claimed is:

1. A method for manufacturing a semiconductor apparatus, the method comprising:
a step of preparing a first semiconductor substrate, a second semiconductor substrate including a first semiconductor layer and a second semiconductor layer, and a third semiconductor substrate;
a bonding step of bonding the second semiconductor substrate and the third semiconductor substrate to one main surface of the first semiconductor substrate; and
a thinning step of removing at least the second semiconductor layer of the second semiconductor substrate by wet etching after the bonding step, wherein
the first semiconductor layer includes a P− type impurity region or an N− type impurity region, the second semiconductor layer includes a P+ region, and
an etching rate of an etchant used in the thinning step for the second semiconductor layer is higher than an etching rate for the first semiconductor layer.

2. The method according to claim 1, wherein
the third semiconductor substrate includes a third semiconductor layer and a fourth semiconductor layer,
in the bonding step, the second semiconductor substrate and the third semiconductor substrate are bonded to the one main surface such that the first semiconductor layer and the third semiconductor layer are disposed along a plane parallel to the one main surface,
an etching rate of the etchant used in the thinning step for the fourth semiconductor layer is higher than an etching rate for the third semiconductor layer, and
at least the fourth semiconductor layer of the third semiconductor substrate is removed in the thinning step.

3. The method according to claim 2, wherein
the third semiconductor layer includes a P− type impurity region or an N− type impurity region, and the fourth semiconductor layer includes a P+ region.

4. The method according to claim 2, wherein
in the first semiconductor layer and the third semiconductor layer, a maximum value of a boron concentration in a depth range of 100 nm from a surface opposite to the one main surface is lower than 1×10¹⁹ [atoms/cm³].

5. The method according to claim 2, wherein
a boron concentration in each of the second semiconductor layer and the fourth semiconductor layer is higher than 1×10¹⁹ [atoms/cm³].

6. The method according to claim 1, wherein
the etchant contains HF, and HNO₃, and CH₃COOH.

7. The method according to claim 1, wherein
the bonding of the first semiconductor substrate and the second semiconductor substrate and the bonding of the first semiconductor substrate and the third semiconductor substrate performed in the bonding step include at least metal bonding.

8. The method according to claim 1, wherein
the bonding of the first semiconductor substrate and the second semiconductor substrate and the bonding of the first semiconductor substrate and the third semiconductor substrate performed in the bonding step include metal bonding of Cu—Cu and covalent bonding of silicon oxide.

9. The method according to claim 1, wherein
the one main surface of the first semiconductor substrate is larger in size in plan view than the second semiconductor substrate and the third semiconductor substrate, and
the method comprises, after the bonding step, a step of depositing silicon oxide around the second semiconductor substrate and the third semiconductor substrate.

10. The method according to claim 9, comprising
after the thinning step, a planarization step of planarizing an upper surface of the silicon oxide and upper surfaces of the second semiconductor substrate and the third semiconductor substrate.

11. The method according to claim 1, wherein
the first semiconductor substrate includes a circuit portion, and each of the second semiconductor substrate and the third semiconductor substrate includes an imaging element.

12. The method according to claim 1, wherein
the first semiconductor substrate includes a circuit portion, the second semiconductor substrate includes an imaging element, and the third semiconductor substrate is a dummy substrate.

13. The method according to claim 1, wherein
the first semiconductor substrate includes an imaging element, and each of the second semiconductor substrate and the third semiconductor substrate includes a circuit portion.

14. The method according to claim 1, wherein
the first semiconductor substrate includes an imaging element, the second semiconductor substrate includes a circuit portion, and the third semiconductor substrate is a dummy substrate.

15. The method according to claim 1, comprising
a dicing step of separating a portion where the first semiconductor substrate and the second semiconductor substrate are bonded to each other and a portion where the first semiconductor substrate and the third semiconductor substrate are bonded to each other.

16. A semiconductor apparatus comprising: a first semiconductor substrate including an imaging element; and a second semiconductor substrate including a circuit portion,
wherein
a main surface of the first semiconductor substrate, and a main surface of the second semiconductor substrate are bonded to each other,
the main surface of the second semiconductor substrate is larger in area than the main surface of the first semiconductor substrate,
the first semiconductor substrate includes a P− type impurity region or an N− type impurity region at a position where a distance from a surface opposite to the second semiconductor substrate exceeds 100 nm, and a maximum value of a P type impurity concentration in a range within 100 nm from the surface opposite to the second semiconductor substrate is higher than a P type impurity concentration in the P− type impurity region or the N− type impurity region and lower than 1×10¹⁹ [atoms/cm³].

17. A semiconductor apparatus comprising: a first semiconductor substrate including a circuit portion; and a second semiconductor substrate including an imaging element,
wherein
a main surface of the first semiconductor substrate, and a main surface of the second semiconductor substrate are bonded to each other,
the main surface of the second semiconductor substrate is larger in area than the main surface of the first semiconductor substrate,
the first semiconductor substrate includes a P− type impurity region or an N− type impurity region at a position where a distance from a surface opposite to the second semiconductor substrate exceeds 100 nm, and a maximum value of a P type impurity concentration in a range within 100 nm from the surface opposite to the second semiconductor substrate is higher than a P type impurity concentration in the P− type impurity region or the N− type impurity region and lower than 1×10¹⁹ [atoms/cm³].

18. A semiconductor apparatus comprising: a first semiconductor substrate; a second semiconductor substrate; and a third semiconductor substrate,
wherein
the second semiconductor substrate and the third semiconductor substrate are bonded to a main surface of a first semiconductor substrate that is larger in area than a main surface of the second semiconductor substrate and a main surface of the third semiconductor substrate,
a main surface of the second semiconductor substrate that is opposite to the first semiconductor substrate and a main surface of the third semiconductor substrate that is opposite to the first semiconductor substrate are disposed along a plane parallel to the main surface of the first semiconductor substrate,
the second semiconductor substrate and the third semiconductor substrate include a P− type impurity region or an N− type impurity region at a position where a distance from a surface opposite to the first semiconductor substrate exceeds 100 nm, and a maximum value of a P type impurity concentration in a range within 100 nm from the surface opposite to the first semiconductor substrate is higher than a P type impurity concentration in the P− type impurity region or the N− type impurity region and lower than 1×10¹⁹ [atoms/cm³].

19. The semiconductor apparatus according to claim 18, wherein
a bonding portion between the first semiconductor substrate and the second semiconductor substrate and a bonding portion between the first semiconductor substrate and the third semiconductor substrate include at least metal bonding.

20. The semiconductor apparatus according to claim 18, wherein
a bonding portion between the first semiconductor substrate and the second semiconductor substrate and a bonding portion between the first semiconductor substrate and the third semiconductor substrate include metal bonding of Cu—Cu and covalent bonding of silicon oxide.

21. The semiconductor apparatus according to claim 18, wherein
silicon oxide is disposed around the second semiconductor substrate and the third semiconductor substrate on the main surface of the first semiconductor substrate.

22. The semiconductor apparatus according to claim 21, wherein
an upper surface of the silicon oxide and upper surfaces of the second semiconductor substrate and the third semiconductor substrate are flat.

23. The semiconductor apparatus according to claim 18, wherein
the first semiconductor substrate includes a circuit portion, and each of the second semiconductor substrate and the third semiconductor substrate includes an imaging element.

24. The semiconductor apparatus according to claim 18, wherein
the first semiconductor substrate includes a circuit portion, the second semiconductor substrate includes an imaging element, and the third semiconductor substrate is a dummy substrate.

25. The semiconductor apparatus according to claim 18, wherein
the first semiconductor substrate includes an imaging element, and each of the second semiconductor substrate and the third semiconductor substrate includes a circuit portion.

26. The semiconductor apparatus according to claim 18, wherein
the first semiconductor substrate includes an imaging element, the second semiconductor substrate includes a circuit portion, and the third semiconductor substrate is a dummy substrate.
